(19) United States
(12) Patent Application Publication
(10) Pub. No.: US 2026/0142439 A1
(43) Pub. Date: May 21, 2026

(54) SEMICONDUCTOR OPTICAL INTEGRATED DEVICE AND METHOD OF MANUFACTURING SEMICONDUCTOR OPTICAL INTEGRATED DEVICE

(71) Applicant: Mitsubishi Electric Corporation, Tokyo (JP)

(72) Inventor: Akitsugu NIWA, Tokyo (JP)

(73) Assignee: Mitsubishi Electric Corporation, Tokyo (JP)

(21) Appl. No.: 19/115,016

(22) PCT Filed: Jan. 27, 2023
(86) PCT No.: PCT/JP2023/002546

§ 371 Date: Mar. 25, 2025

(51) Int. Cl. H01S 5/068; H01S 5/026

(52) U.S. Cl. CPC H01S 5/06825; H01S 5/0265

(57) ABSTRACT

A semiconductor optical integrated device includes a first clad layer (20) of a first conductivity type, a transparent waveguide layer (22) formed on the first clad layer (20) and configured to generate a laser beam, a modulation layer (24) formed on the first clad layer (20), connected to the transparent waveguide layer (22) at a lower part, and configured to modulate the laser beam, an undoped portion (26) formed between the transparent waveguide layer (22) and the modulation layer (24) on a connection portion between the transparent waveguide layer (22) and the modulation layer (24), and a second clad layer (28) of a second conductivity type formed on the transparent waveguide layer (22), the modulation layer (24), and the undoped portion (26).

### FIELD

The present disclosure relates to a semiconductor optical integrated device and a method of manufacturing the semiconductor optical integrated device.

### BACKGROUND

A semiconductor optical integrated device used for an optical communication network and a datacenter is required to have high reliability. To enhance reliability of the semiconductor optical integrated device, it is important to improve ESD (Electro Static Discharge) resistance.

PTL 1 discloses a semiconductor optical integrated device in which an ESD protection portion is formed in parallel with an active layer in order to enhance ESD resistance.

### CITATION LIST

### Patent Literature

[PTL 1] JP 2010-287604 A

### SUMMARY

### Technical Problem

However, to manufacture the semiconductor optical integrated device disclosed in PTL 1, there is a problem in that a complicated step of forming the ESD protection portion is necessary in addition to a normal step, which reduces productivity.

The present disclosure is made to solve the above-described problem, and an object of the present disclosure is to obtain a semiconductor optical integrated device that realizes improvement of ESD resistance while suppressing reduction in productivity, and a method of manufacturing the semiconductor optical integrated device.

### Solution to Problem

A semiconductor optical integrated device according to the disclosure includes a first clad layer of a first conductivity type, a transparent waveguide layer formed on the first clad layer and configured to generate a laser beam, a modulation layer formed on the first clad layer, connected to the transparent waveguide layer at a lower part, and configured to modulate the laser beam, an undoped portion formed between the transparent waveguide layer and the modulation layer on a connection portion between the transparent waveguide layer and the modulation layer, and a second clad layer of a second conductivity type formed on the transparent waveguide layer, the modulation layer, and the undoped portion.

A first method of manufacturing a semiconductor optical integrated device according to the disclosure includes a step of forming a modulation layer on a first clad layer of a first conductivity type, a step of forming a mask layer in a stripe shape, on the modulation layer, a step of etching the modulation layer by using the mask layer as a mask, a step of washing a side surface of the etched modulation layer by wet treatment to incline the side surface inward, a step of forming a transparent waveguide layer having a lower part connected to the modulation layer, by using the mask layer as a selective growth mask, a step of forming an undoped portion between the transparent waveguide layer and the modulation layer on a connection portion between the transparent waveguide layer and the modulation layer, a step of removing the mask layer and a step of forming a second clad layer of a second conductivity type on the transparent waveguide layer, the modulation layer, and the undoped portion.

A second method of manufacturing a semiconductor optical integrated device according to the disclosure includes a step of forming a transparent waveguide layer on a first clad layer of a first conductivity type, a step of forming a mask layer in a stripe shape, on the transparent waveguide layer, a step of etching the transparent waveguide layer by using the mask layer as a mask, a step of washing a side surface of the etched transparent waveguide layer by wet treatment to incline the side surface inward, a step of forming a modulation layer having a lower part connected to the transparent waveguide layer, by using the mask layer as a selective growth mask, a step of forming an undoped portion between the transparent waveguide layer and the modulation layer on a connection portion between the transparent waveguide layer and the modulation layer, a step of removing the mask layer and a step of forming a second clad layer of a second conductivity type on the transparent waveguide layer, the modulation layer, and the undoped portion.

### Advantageous Effects of Invention

According to the present disclosure, it is possible to obtain the semiconductor optical integrated device that realizes improvement of ESD resistance while suppressing reduction in productivity, and the method of manufacturing the semiconductor optical integrated device.

### Brief Description of Drawings

FIG. 1 illustrates a semiconductor optical integrated device according to Embodiment 1.

FIG. 2 illustrates a semiconductor optical integrated device according to a comparative example.

FIG. 3 is a diagram illustrating a method of manufacturing the semiconductor optical integrated device according to Embodiment 1.

FIG. 4 is a diagram illustrating a method of manufacturing the semiconductor optical integrated device according to Embodiment 1.

FIG. 5 is a diagram illustrating a method of manufacturing the semiconductor optical integrated device according to Embodiment 1.

FIG. 6 is a diagram illustrating a method of manufacturing the semiconductor optical integrated device according to Embodiment 1.

FIG. 7 is a diagram illustrating a method of manufacturing the semiconductor optical integrated device according to Embodiment 1.

FIG. 8 is a diagram illustrating a method of manufacturing the semiconductor optical integrated device according to Embodiment 1.

FIG. 9 is a diagram illustrating a method of manufacturing the semiconductor optical integrated device according to Embodiment 1.

FIG. 10 is a diagram illustrating a method of manufacturing the semiconductor optical integrated device according to Embodiment 1.

FIG. 11 illustrates a semiconductor optical integrated device according to a modification of Embodiment 1.

FIG. 12 illustrates a semiconductor optical integrated device according to Embodiment 2.

FIG. 13 illustrates a semiconductor optical integrated device according to Embodiment 3.

FIG. 14 illustrates a semiconductor optical integrated device according to Embodiment 4.

FIG. 15 illustrates a semiconductor optical integrated device obtained by combining the features of Embodiments 3 and 4.

### DESCRIPTION OF EMBODIMENTS

### Embodiment 1

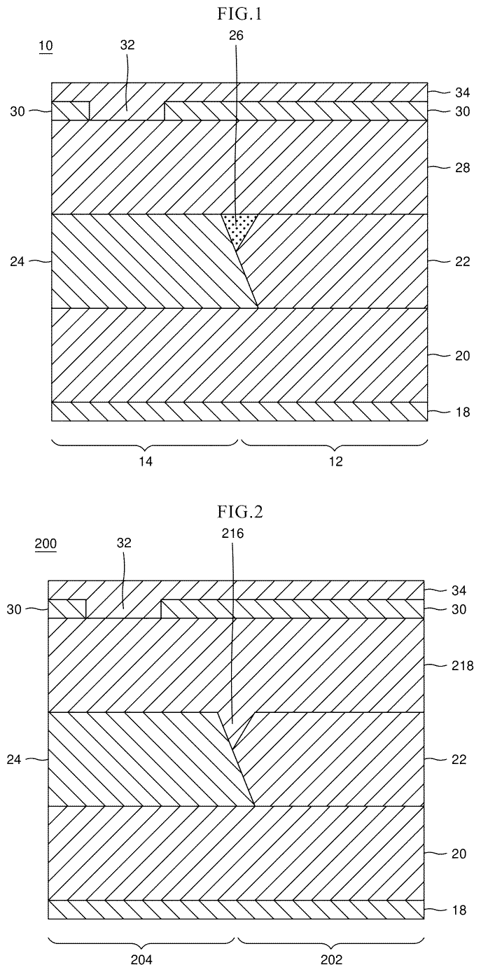

FIG. 1 illustrates a semiconductor optical integrated device 10 according to Embodiment 1. The semiconductor optical integrated device 10 is an electro-absorption modulator integrated laser (EML). FIG. 1 is a cross-sectional view of the semiconductor integrated optical device 10 as viewed from a direction perpendicular to a resonance direction of a laser beam. The semiconductor optical integrated device 10 includes a laser generation portion 12 generating the laser beam, and an electro-absorption optical modulation portion 14 modulating the laser beam generated by the laser generation portion 12. The laser generation portion 12 and the electro-absorption optical modulation portion 14 are formed adjacently to each other. The laser beam modulated by the electro-absorption optical modulation portion 14 is emitted from an end surface on a side opposite to the laser generation portion 12. The semiconductor optical integrated device 10 includes a rear-surface electrode 18, a first clad layer 20, a transparent waveguide layer 22, a modulation layer 24, an undoped portion 26, a second clad layer 28, an insulating film 30, and a front-surface electrode 34.

The first clad layer 20 is a semiconductor substrate made of, for example, n-type (first conductivity type) InP. The rear-surface electrode 18 is formed below the first clad layer 20.

The transparent waveguide layer 22 is formed on the first clad layer 20 on the laser generation portion 12 side. The transparent waveguide layer 22 is made of, for example, InGaAsP.

The modulation layer 24 connected to the transparent waveguide layer 22 at a lower part is formed on the first clad layer 20 on the electro-absorption optical modulation portion 14 side. The modulation layer 24 is made of, for example, AlGaInAs. A connection portion between the transparent waveguide layer 22 and the modulation layer 24 is inclined toward the modulation layer 24.

The undoped portion 26 is formed between the transparent waveguide layer 22 and the modulation layer 24 on the connection portion between the transparent waveguide layer 22 and the modulation layer 24. The undoped portion 26 is a region low in impurity concentration, and is made of, for example, InP. Alternatively, the undoped portion 26 may be made of InGaAsP low in Ga content and As content. The impurity concentration is 3×10¹⁶ cm⁻³ or less.

The second clad layer 28 is formed on the transparent waveguide layer 22, the modulation layer 24, and the undoped portion 26. The second clad layer 28 is made of, for example, p-type (second conductivity type) InP.

The insulating film 30 is formed on the second clad layer 28. The insulating film 30 is made of, for example, SiO₂. The insulating film 30 includes an opening 32 above the modulation layer 24.

The front-surface electrode 34 is formed in the opening 32 and on the opening 32 and the insulating film 30. The front-surface electrode 34 is in contact with the second clad layer 28 on the electro-absorption optical modulation portion 14 side in the opening 32.

A semiconductor optical integrated device 200 according to a comparative example and the semiconductor optical integrated device 10 according to the present embodiment are compared. FIG. 2 illustrates a cross-section of the semiconductor optical integrated device 200.

In the semiconductor optical integrated device 200, unlike the semiconductor optical integrated device 10, the undoped portion 26 is not formed, and a corresponding region serves as a part of a p-type second clad layer 218. The region in the semiconductor optical integrated device 200 is referred to as a region 216. During operation of the semiconductor optical integrated device 200, carriers (holes) intrude into the region 216 that is of a p-type. Therefore, a strong electric field occurs at the connection portion between the transparent waveguide layer 22 and the modulation layer 24. When the strong electric field occurs, a possibility of occurrence of ESD destruction is increased at the connection portion.

On the other hand, in the semiconductor optical integrated device 10 according to the present embodiment, the undoped portion 26 is formed, and carriers to not intrude into the region during operation. Therefore, a strong electric field does not occur at the connection portion between the transparent waveguide layer 22 and the modulation layer 24. Therefore, a possibility of occurrence of ESD destruction is low at the connection portion.

A method of manufacturing the semiconductor optical integrated device 10 is described.

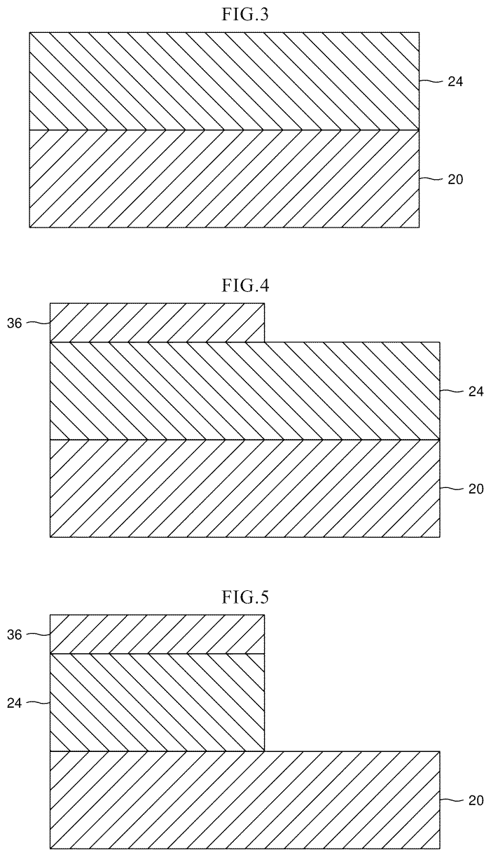

First, as illustrated in FIG. 3, the modulation layer 24 is formed on the first clad layer 20. A formation method is, for example, MOCVD (Metal Organic Chemical Vapor Deposition) method.

Thereafter, an SiO₂ layer is deposited on the modulation layer 24, and photoetching using a resist pattern is performed to form a stripe-shaped mask layer 36 made of SiO₂ as illustrated in FIG. 4.

Thereafter, as illustrated in FIG. 5, dry etching by RIE (Reactive Ion Etching) or ICP (Inductively Coupled Plasma) is performed using the mask layer 36 as a mask, thereby etching the modulation layer 24.

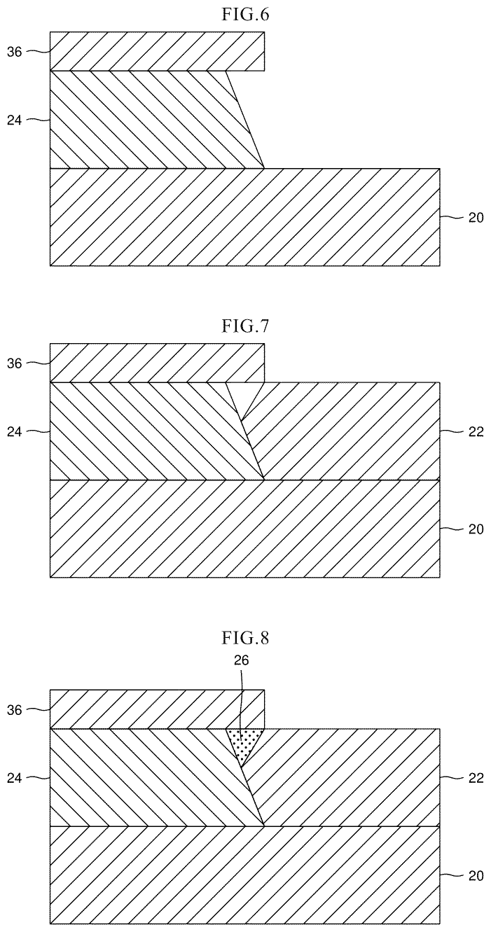

Thereafter, as illustrated in FIG. 6, a side surface of the etched modulation layer 24 is washed by wet treatment using chemical liquid. At this time, the washed side surface is inclined inward.

Thereafter, as illustrated in FIG. 7, the transparent waveguide layer 22 is formed using the mask layer 36 as a selective growth mask. A formation method is, for example, the MOCVD method. A growth temperature is within a range from 600° C. to 650° C. At this time, a cavity is formed below an end part (on transparent waveguide layer 22 side) of the mask layer 36. This is because the end part of the mask layer 36 serves as an eave and raw material gas hardly reach the region.

Thereafter, as illustrated in FIG. 8, the undoped portion 26 is formed. The undoped portion 26 is formed by changing a deposition condition such as a growth temperature and a supply gas flow rate, to control a mass transport amount, as compared with the step of forming the transparent waveguide layer 22. As compared with formation of the transparent waveguide layer 22, the growth temperature is reduced by 30° C. to 100° C. In addition, the gas flow rate is reduced to 50% to 95% of a flow rate during formation of the transparent waveguide layer 22. When the growth temperature is reduced, a growth rate of a (111) plane (inclined surface) and a (110) plane (surface perpendicular to front surface of first clad layer 20) is increased as compared with a (001) plane (surface parallel to the front surface of first clad layer 20), and when the gas flow rate is reduced, growth of the (001) plane is suppressed. As a result, the undoped portion 26 is formed.

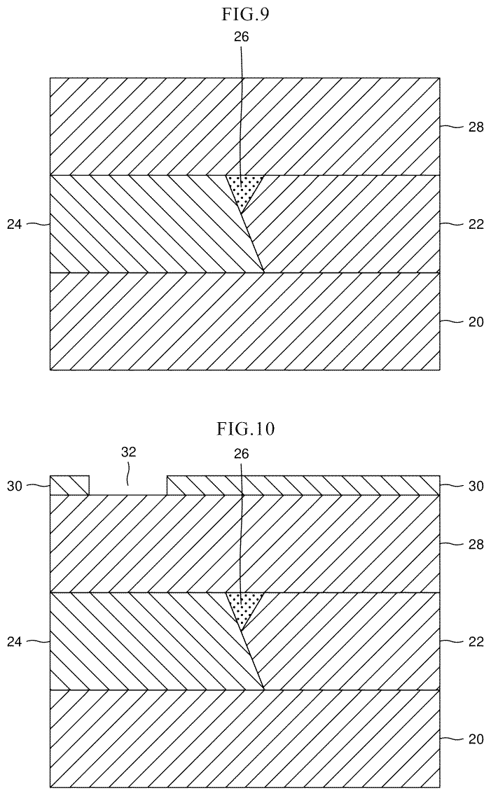

After the mask layer 36 is removed, the second clad layer 28 is formed on the transparent waveguide layer 22, the modulation layer 24, and the undoped portion 26 as illustrated in FIG. 9. A formation method is, for example, the MOCVD method.

Thereafter, as illustrated in FIG. 10, the insulating film 30 including the opening 32 is formed, and the front-surface electrode 34 and the rear-surface electrode 18 are formed. As a result, the semiconductor optical integrated device 10 illustrated in FIG. 1 is obtained.

As described above, according to the present embodiment, since the undoped portion 26 is provided, ESD resistance can be improved. The undoped portion 26 can be formed continuously after formation of the transparent waveguide layer 22, and reduction in productivity by formation of the undoped portion 26 is suppressed.

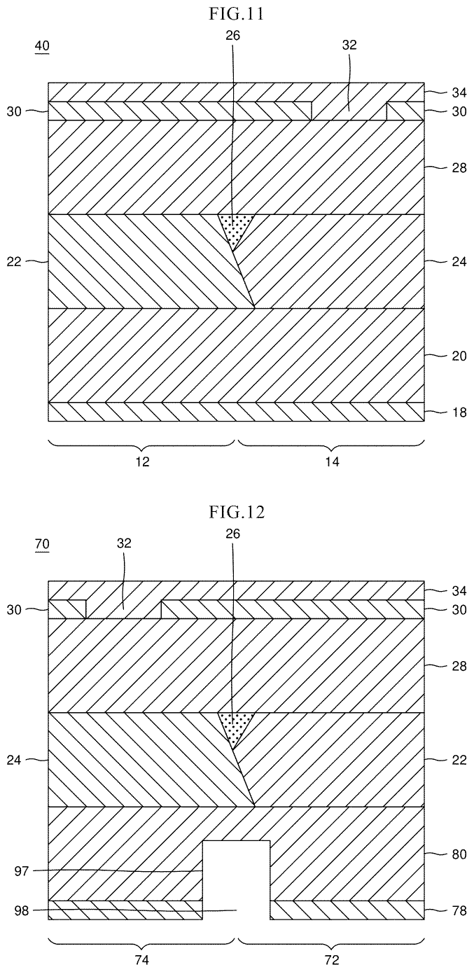

As a modification, the transparent waveguide layer may be formed first, and the modulation layer may be then formed. FIG. 11 illustrates a semiconductor optical integrated device 40 in this case. In FIG. 11, the laser generation portion 12 is positioned on a left side of a paper surface, and the electro-absorption optical modulation portion 14 is positioned on a right side of the paper surface. The connection portion between the transparent waveguide layer 22 and the modulation layer 24 is inclined toward the transparent waveguide layer 22. In the manufacturing method, the transparent waveguide layer and the modulation layer are exchanged in the above-described description. A feature that the transparent waveguide layer is formed first, and the modulation layer is then formed can be applied to the other embodiments described below.

### Embodiment 2

FIG. 12 illustrates a cross-section of a semiconductor optical integrated device 70 according to Embodiment 2. Unlike Embodiment 1, in the semiconductor optical integrated device 70 according to Embodiment 2, a concave part 97 is formed on a lower surface of a first clad layer 80 below the connection portion between the transparent waveguide layer 22 and the modulation layer 24, and a rear-surface electrode 78 includes a rear-surface opening 98 below the concave part 97. The concave part 97 and the rear-surface opening 98 are formed by etching the rear-surface electrode 78 and the lower surface of the first clad layer 80.

In the embodiment, since the concave part 97 is formed, concentration of carriers (electrons) on the connection portion between the transparent waveguide layer 22 and the modulation layer 24 is suppressed. As a result, a strong electric field does not occur at the connection portion between the transparent waveguide layer 22 and the modulation layer 24, which makes it possible to improve ESD resistance. In addition, since the concave part 97 can be formed by removing a part of the first clad layer 80 by etching, reduction in productivity can be suppressed.

The concave part 97 extends up to a side surface parallel to the resonance direction of the laser beam. Therefore, when the semiconductor optical integrated device 70 is joined to a carrier such as a sub-mount, creeping-up of a joining material such as solder is suppressed by the concave part 97. Thus, assembling property is high.

To prevent occurrence of a strong electric field, a thickness of the first clad layer 80 on the concave part 97 is desirably a half or less of a thickness of the transparent waveguide layer 22.

### Embodiment 3

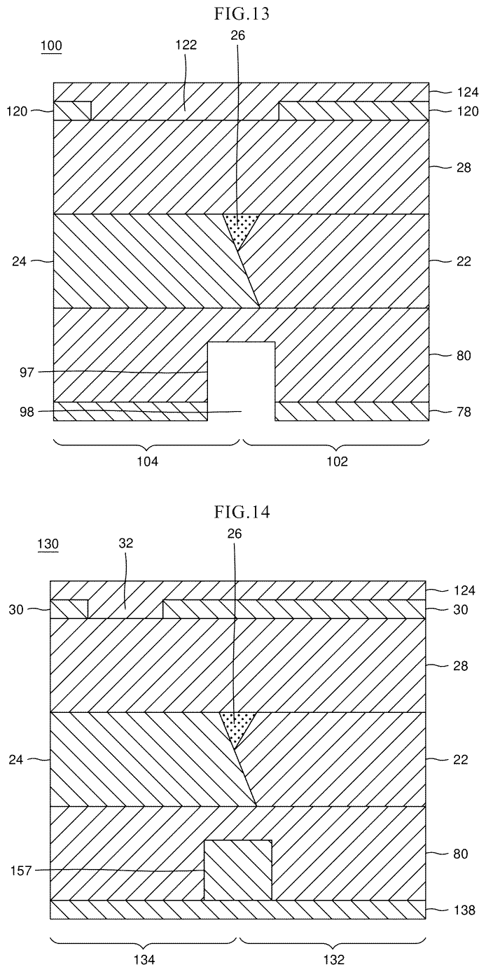

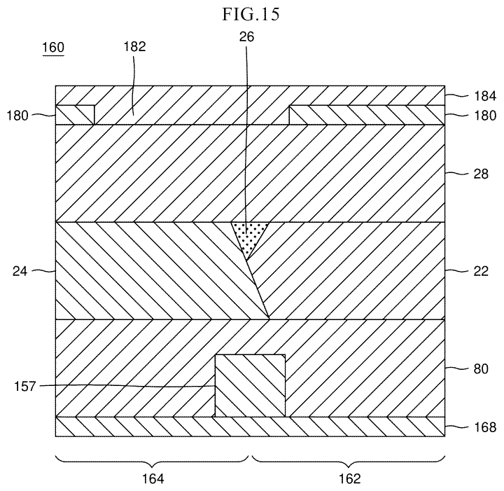

FIG. 13 illustrates a cross-section of a semiconductor optical integrated device 100 according to Embodiment 3. Unlike Embodiment 2, in the semiconductor optical integrated device 100 according to Embodiment 3, an opening 122 extends from above the modulation layer 24 to above the connection portion between the transparent waveguide layer 22 and the modulation layer 24. As a result, a region of a front-surface electrode 124 in contact with the second clad layer 28 extends up to above the connection portion between the transparent waveguide layer 22 and the modulation layer 24. Therefore, a modulation driving region of the modulation layer 24 extends to near the connection portion with the transparent waveguide layer 22. Thus, an extinction ratio of the emitted laser beam is increased.

### Embodiment 4

FIG. 14 illustrates a cross-section of a semiconductor optical integrated device 130 according to Embodiment 4. Unlike Embodiment 2, in the semiconductor optical integrated device 130 according to Embodiment 4, a semi-insulating material or a low dielectric-constant material (BCB (benzocyclobutene), etc.) is embedded in a concave part 157 of the first clad layer 80. An embedding step is performed before formation of a rear-surface electrode 138, and the rear-surface electrode 138 is formed after the embedding step. Therefore, the rear-surface electrode 138 is formed below the concave part 157.

In the present embodiment, concentration of carriers (electrons) on the connection portion between the transparent waveguide layer 22 and the modulation layer 24 is also suppressed. As a result, ESD resistance at the connection portion between the transparent waveguide layer 22 and the modulation layer 24 is improved. Further, one kind of material is simply embedded in the concave part 157. Thus, reduction in productivity is small.

The concave part 157 extends up to a side surface parallel to the resonance direction of the laser beam. Therefore, when the semiconductor optical integrated device 130 is joined to a carrier such as a sub-mount, creeping-up of a joining material such as solder is suppressed by the concave part 157. Thus, assembling property is high.

The features of Embodiment 3 and the features of Embodiment 4 may be combined. FIG. 15 illustrates a cross-section of a semiconductor optical integrated device 160 in this case.

As described above, in all of the embodiments, the first clad layer and the second clad layer are of an n-type and a p-type, respectively; however, the first clad layer and the second clad layer may be of a p-type and an n-type, respectively. In this case, the first conductivity type and the second conductivity type are respectively a p-type and an n-type.

### REFERENCE SIGNS LIST

10,40,70,100,130,160,200 semiconductor optical integrated device, 12,72,102,132,162,202 laser generation portion, 14,74,104,134,164,204 electro-absorption optical modulation portion, 18,78,138,168 rear-surface electrode, 20,80 first clad layer, 22 transparent waveguide layer, 24 modulation layer, 26 undoped portion, 28,218 second clad layer, 30,120,180 insulating film, 32,122,182 opening, 34,124,184 front-surface electrode, 36 mask layer, 216 region, 97,157 concave part, 98 rear-surface opening

1. A semiconductor optical integrated device, comprising:
a first clad layer of a first conductivity type;
a transparent waveguide layer formed on the first clad layer and configured to generate a laser beam;
a modulation layer formed on the first clad layer, connected to the transparent waveguide layer at a lower part, and configured to modulate the laser beam;
an undoped portion formed between the transparent waveguide layer and the modulation layer on a connection portion between the transparent waveguide layer and the modulation layer; and
a second clad layer of a second conductivity type formed on the transparent waveguide layer, the modulation layer, and the undoped portion.

2. The semiconductor optical integrated device according to claim 1,
wherein a concave part is formed on a lower surface of the first clad layer below the connection portion.

3. The semiconductor optical integrated device according to claim 2, comprising:
an insulating film formed on the second clad layer, and provided with an opening extending from above the modulation layer to above the connection portion; and
a front-surface electrode formed in the opening and on the opening and the insulating film, and in contact with the second clad layer in the opening.

4. The semiconductor optical integrated device according to claim 2,
wherein a semi-insulating material or a low dielectric-constant material is embedded in the concave part.

5. A method of manufacturing a semiconductor optical integrated device, the method comprising:
forming a modulation layer on a first clad layer of a first conductivity type;
forming a mask layer in a stripe shape, on the modulation layer;
etching the modulation layer by using the mask layer as a mask;
washing a side surface of the etched modulation layer by wet treatment to incline the side surface inward;
forming a transparent waveguide layer having a lower part connected to the modulation layer, by using the mask layer as a selective growth mask;
forming an undoped portion between the transparent waveguide layer and the modulation layer on a connection portion between the transparent waveguide layer and the modulation layer;
removing the mask layer; and
forming a second clad layer of a second conductivity type on the transparent waveguide layer, the modulation layer, and the undoped portion.

6. The method of manufacturing the semiconductor optical integrated device according to claim 5,
wherein, when forming the undoped portion, a growth temperature is reduced by 30° C. to 100° C., and a gas flow rate is reduced to 50% to 95% as compared with when forming the transparent waveguide layer.

7. A method of manufacturing a semiconductor optical integrated device, the method comprising:
forming a transparent waveguide layer on a first clad layer of a first conductivity type;
forming a mask layer in a stripe shape, on the transparent waveguide layer;
etching the transparent waveguide layer by using the mask layer as a mask;
washing a side surface of the etched transparent waveguide layer by wet treatment to incline the side surface inward;
forming a modulation layer having a lower part connected to the transparent waveguide layer, by using the mask layer as a selective growth mask;
forming an undoped portion between the transparent waveguide layer and the modulation layer on a connection portion between the transparent waveguide layer and the modulation layer;
removing the mask layer; and
forming a second clad layer of a second conductivity type on the transparent waveguide layer, the modulation layer, and the undoped portion.

8. The method of manufacturing the semiconductor optical integrated device according to claim 7,
wherein, when forming the undoped portion, a growth temperature is reduced by 30° C. to 100° C., and a gas flow rate is reduced to 50% to 95% as compared with when of forming the modulation layer.

9. The method of manufacturing the semiconductor optical integrated device according to claim 5, comprising
forming a concave part by etching a lower surface of the first clad layer below the connection portion.

10. The method of manufacturing the semiconductor optical integrated device according to claim 9, comprising:
forming an insulating film provided with an opening, on the second clad layer, the opening extending from above the modulation layer to above the connection portion; and
forming a front-surface electrode in the opening and on the opening and the insulating film, the front-surface electrode being in contact with the second clad layer in the opening.

11. The method of manufacturing the semiconductor optical integrated device according to claim 9, comprising
embedding a semi-insulating material or a low dielectric-constant material in the concave part.

12. The method of manufacturing the semiconductor optical integrated device according to claim 7, comprising
forming a concave part by etching a lower surface of the first clad layer below the connection portion.

13. The method of manufacturing the semiconductor optical integrated device according to claim 12, comprising:
forming an insulating film provided with an opening, on the second clad layer, the opening extending from above the modulation layer to above the connection portion; and
forming a front-surface electrode in the opening and on the opening and the insulating film, the front-surface electrode being in contact with the second clad layer in the opening.

14. The method of manufacturing the semiconductor optical integrated device according to claim 12, comprising
embedding a semi-insulating material or a low dielectric-constant material in the concave part.
